(19) United States
(12) Patent Application Publication
(10) Pub. No.: US 2026/0092392 A1
(43) Pub. Date: Apr. 2, 2026

(54) METHOD FOR PRODUCING A SINGLE CRYSTAL OF SILICON WHICH IS DOPED WITH N-TYPE DOPANT ACCORDING TO THE CZ METHOD

(71) Applicant: Siltronic AG, Munich (DE)

(72) Inventors: Georg Raming, Tann (DE); Matthias Daniel, Freiberg (DE); Johann-Andreas Huber, Ainring (DE)

(21) Appl. No.: 19/113,458

(22) PCT Filed: Sep. 28, 2023
(86) PCT No.: PCT/EP2023/076932

§ 371 Date: Mar. 20, 2025

(30) Foreign Application Priority Data
Oct. 14, 2022 (EP) 22201615.6

(51) Int. Cl. C30B 15/04; C30B 15/14; C30B 15/20; C30B 29/06

(52) U.S. Cl. CPC C30B 15/04; C30B 15/14; C30B 15/20; C30B 29/06

(57) ABSTRACT

A process produces a single silicon crystal doped with n-type dopant by pulling the single crystal, surrounded by a heat shield, in a reactor chamber, by the CZ method, from a melt. A solid dopant is heated in a dopant crucible of a sublimating unit outside the reactor chamber to a temperature at which a gaseous dopant is formed. The gaseous dopant is supplied through a conduit to a surface of the melt, including by: bringing a control valve, which is between the sublimating unit and the reactor chamber, into a mandated open state as soon as a pressure difference between the pressure in the sublimating unit and the pressure in the reactor chamber has grown to a predetermined value; and controlling the open state of the control valve with a setpoint pressure in the sublimating unit as command variable and the pressure difference as controlled variable of the control.

### CROSS REFERENCE TO RELATED APPLICATIONS

This application is a U.S. National Phase application under 35 U.S.C. § 371 of International Application No. PCT/EP2023/076932, filed on Sep. 28, 2023, and claims benefit to European Patent Application No. EP 22201615.6, filed on Oct. 14, 2022. The International Application was published in German on Apr. 18, 2024 as WO 2024/078888 A1 under PCT Article 21(2).

### FIELD

The present application is directed to a process for producing a single silicon crystal doped with n-type dopant by pulling the single crystal in a reactor chamber by the Czochralski (CZ) method from a melt contained in a crucible.

### BACKGROUND

Single silicon crystals containing a comparatively large amount of n-type dopant are needed primarily as raw materials for the production of power semiconductor components.

Sublimating dopant elements such as phosphorus, arsenic or antimony are contacted with the melt typically when they are in gaseous state. The challenge here is to ensure a sufficiently high concentration of dopant in the melt, notwithstanding a high vapor pressure of the dopant. Furthermore, the introduction of dopant must be regulated with the utmost precision in order to prevent dislocations forming that end the monocrystalline growth of crystal.

WO 2021/115 904 A1 describes a process whereby dopant gas is generated in a sublimating facility and is passed together with a carrier gas through a conduit into the reactor chamber until reaching an annular channel at a lower end of a heat shield.

US 2010/0 294 999 A1 describes the subliming of solid dopant in a heated unit within the reactor chamber and the controlling of the sublimation rate and passing of resultant dopant gas together with a carrier gas through a conduit to the melt.

### SUMMARY

In an embodiment, the present disclosure provides a process that produces a single silicon crystal doped with n-type dopant by pulling the single crystal, surrounded by a heat shield, in a reactor chamber, by the CZ method, from a melt. A solid dopant is heated in a dopant crucible of a sublimating unit outside the reactor chamber to a temperature at which a gaseous dopant is formed. The gaseous dopant is supplied through a conduit to a surface of the melt, including by: bringing a control valve, which is between the sublimating unit and the reactor chamber, into a mandated open state as soon as a pressure difference between the pressure in the sublimating unit and the pressure in the reactor chamber has grown to a predetermined value; and controlling the open state of the control valve with a setpoint pressure in the sublimating unit as command variable and the pressure difference as controlled variable of the control.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 shows a vertical section through a reactor chamber and a sublimating unit suitable for implementing aspects of the present disclosure;

FIG. 2 shows an enlarged detail from FIG. 1; and

FIG. 3 shows the profile of the electrical resistivity R of a single silicon crystal as a function of the axial position P of the cylindrical portion of the single crystal.

### DETAILED DESCRIPTION

Aspects of the present disclosure are directed to providing a simple means to make the dopant distribution over the axial length of a cylindrical portion of the single crystal extremely uniform, irrespective of the length of the cylindrical portion.

An aspect of the present disclosure provides a process for producing a single silicon crystal doped with n-type dopant by pulling the single crystal, surrounded by a heat shield having a lower end, in a reactor chamber by the CZ method from a melt contained in a crucible, comprising: heating solid dopant in a dopant crucible of a sublimating unit outside the reactor chamber by means of a crucible heater to a temperature at which gaseous dopant is formed; supplying the gaseous dopant in the form of a volume stream of dopant gas through a conduit having a lower end to a surface of the melt, which comprises bringing a control valve between the sublimating unit and the reactor chamber into a mandated open state as soon as a pressure difference between the pressure in the sublimating unit and the pressure in the reactor chamber has grown to a predetermined value; and controlling the open state of the control valve with a setpoint pressure in the sublimating unit as command variable and the pressure difference as controlled variable of the control.

Aspects of the present disclosure make it possible, during the pulling of a single crystal, to pass a virtually constant stream of dopant gas to the melt over a comparatively long period and to reload solid dopant as and when required in order to ensure continued supply of dopant gas to the melt. The solution is simple and reliable.

The gaseous dopant is passed without or together with a carrier gas such as argon as a volume stream of dopant gas to the melt. The carrier gas is used in particular to stabilize the stream of gaseous dopant if the concentration of gaseous dopant is comparatively low. The supply of carrier gas is controlled preferably by means of a mass flow controller (MFC).

Solid dopant may be charged to the dopant crucible before and/or during the pulling of a single crystal. To reload the dopant crucible with solid dopant, the conduit outside the reactor chamber is interrupted by complete closure of the control valve. For safety purposes, an isolation valve is preferably activated as well, this valve possibly being disposed between the reactor chamber and the control valve. The isolation valve makes certain that reliable access to the sublimating unit is ensured irrespective of the tightness of the control valve. The temperature of the dopant crucible and hence the temperature in the sublimating unit is preferably raised shortly before the solid dopant contained therein is used up. This ensures that the dopant has fully escaped before the sublimating unit is opened. The escape of the dopant may be monitored via the associated pressure drop in the sublimating unit.

The sublimating unit comprises a housing which accommodates the dopant crucible and provides an access to the dopant crucible. The housing preferably has a double-wall construction and can be actively cooled by means of a cooling circuit.

As well as the crucible heater, there are preferably other heaters present, especially in order to counteract resublimation of the dopant; examples include an interior heater for the housing, an exterior heater for the control valve and the optional isolation valve and those regions of the conduit that are located outside the reactor chamber. A further heater may be provided for heating valves for introducing the carrier gas and ambient air into the sublimating unit. For red phosphorus as dopant, the sublimation temperature is 362° C. at a pressure of 10 000 Pa; for arsenic, the sublimation temperature at this pressure is 508° C. In particular, the temperature of the dopant-carrying conduit ought to be above the corresponding sublimation temperature.

The pressure is measured in the reactor chamber and in the sublimating unit. The open condition of the control valve is made dependent on the difference between the pressures in the sublimating unit and in the reactor chamber, and is adjusted via a control valve actuator. The actuator adjusts the stroke of an element which determines the flow through the valve, such as the position of a stopper which is able to interrupt flow through the valve. The actuator preferably operates electrically and forms the controlling element of a control. During the supplying of the gaseous dopant to the surface of the melt, the pressure in the sublimating unit is greater than the pressure in the reactor chamber.

In order to ensure that the volume stream of dopant gas reaches the melt in a reproducible and regulated way during a procedure of pulling a single silicon crystal, the volume stream is passed through the control valve preferably only after a stabilization phase. The stabilization phase comprises the heating of the dopant crucible, with the control valve closed, to a temperature which is below the temperature at which the solid dopant begins to sublime, until the pressure in the sublimating unit has risen to a predetermined value. After the stabilization phase, the dopant crucible is heated to a temperature which lies above the temperature at which the solid dopant begins to sublime. The rate (evaporation rate) at which the solid dopant sublimes is determined in particular by the temperature to which the dopant crucible is heated. A further pressure increase ensuing in the sublimating unit when the temperature of the dopant crucible heater is constant or slightly rising indicates the start of sublimation. The control valve is opened as soon as the difference between the pressure in the sublimating unit and the pressure in the reactor chamber has grown to a predetermined value. The pressure difference is preferably at least 1000 Pa, more preferably 5000 to 10 000 Pa. The opening condition of the control valve is subsequently controlled by means of a control valve actuator as part of a control, with a setpoint pressure in the sublimating unit as command variable and with the pressure difference as controlled variable of the control. The control preferably takes the form of proportional-integral-derivative (PID) control. The pressure in the sublimating unit remains virtually constant, except for periodic pressure fluctuations because of the control, until a pressure drop occurs because of the dwindling supply of solid dopant in the dopant crucible. When the pressure falls to an envisaged value, the control valve is also closed.

The dopant crucible can be recharged with solid dopant, should it be necessary to replace dopant that has escaped from the melt. This may be the case if, after development of a dislocation, the crystal is remelted and a new single-crystal pulling campaign is commenced, or if the stock of dopant in the sublimating unit is exhausted owing to the length of the cylindrical portion of the growing single crystal. In that case, with the control valve closed and any isolation valve closed, the sublimating unit is purged and cooled and the required amount of additional solid dopant is placed in the dopant crucible.

The supply of the volume stream of dopant gas through the conduit to the surface of the melt preferably begins before the pulling of a cylindrical portion of the single crystal, such as straight after the contacting of a seed crystal with the melt or before or during the pulling of a conical portion of the single crystal, for example. An alternative possibility is to begin this process only at the start of during the pulling of the cylindrical portion. Independently of this, the melt may have been enriched with dopant even before the supplying of the volume stream of dopant gas, by virtue, for example, of the immersion of a doping bell with solid dopant into the silicon melt.

The lower end of the conduit, at which the volume stream of dopant gas emerges, is preferably disposed at the same height above the melt as the lower end of a heat shield which surrounds the growing single crystal. Moreover, the lower end of the conduit is preferably located between the lower end of the heat shield and the wall of the crucible with the melt. It is also preferable for the conduit in the reactor chamber to be disposed such that it passes through the wall of the heat shield. In the region of the wall of the reactor chamber, where the conduit may be cooled with water, said conduit consists preferably of metal, such as of stainless steel, for example, and is exposed there to a temperature of not more than 600° C. In the surroundings of the growing single crystal and relatively hot graphite parts, the hot zone, temperature-stable material must be used, such as graphite, a carbon fiber-reinforced composite (CFC) material and/or quartz. Particularly preferred is the subdivision of the conduit in the reactor chamber into an upper portion of stainless steel, a middle portion of CFC, and a lower portion of quartz clad at its lower end with CFC. The cladding protects the quartz tube from overheating.

The present disclosure is described further below with reference to the drawings.

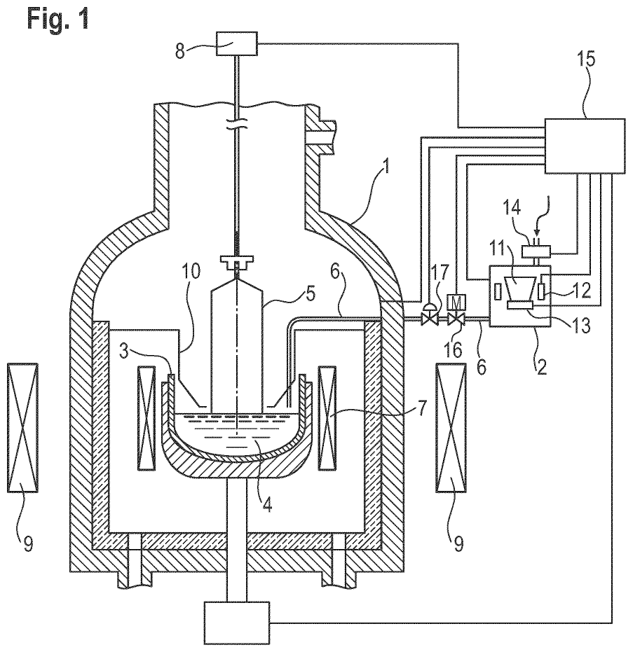

FIG. 1 shows a vertical section through a reactor chamber 1 and a sublimating unit 2 which are suitable for implementing aspects of the present disclosure. Disposed in the reactor chamber 1 is a crucible 3 with a silicon melt 4 which in the course of the pulling of a single crystal 5 is doped from the melt with gaseous n-type dopant which is passed through a conduit 6 to the surface of the melt 4. The melt 4 is kept liquid by means of a heating apparatus 7 which surrounds the crucible 3. The single crystal 5 is surrounded by a heat shield 10 which shields thermal radiation of the heating apparatus 7. While the single crystal 5 is rotated and pulled from the melt by means of a pulling apparatus 8, the crucible 3 is raised and rotated. Causing a magnetic field, such as a horizontal magnetic field, to act on the melt 4 by means of one or more magnetic field coils 9 disposed around the reactor chamber 1 is possible but not absolutely necessary. During the pulling of the single crystal 5, the reactor chamber 1 is purged, by means of a stream of argon passed through it, for example.

The gaseous dopant is generated in the sublimating unit 2, which is located outside the reactor chamber, and is guided from there in the form of a volume stream of dopant gas through the conduit 6 to the surface of the melt 4. The volume stream may contain a portion of carrier gas, argon being an example, which is passed into the sublimating unit via a mass flow controller 14. For generating the gaseous dopant, solid dopant, red phosphorus being an example, is introduced into a dopant crucible 11, and the dopant crucible 11 is heated by means of a crucible heater 12 in the sublimating unit 2. The sublimating unit 2 may possess a weighing cell 13 providing information on the current weight of solid dopant in the dopant crucible 11. On its path through the conduit 6, the volume stream of dopant gas, after leaving the sublimating unit 2 and before entering the reactor chamber 1, passes through a control valve 16 and optionally an isolation valve 17.

The pressure and the temperature in the reactor chamber 1 and in the sublimating unit 2 are transmitted by sensors to a controller 15 which is used to control the supply of dopant gas to the surface of the melt 4. In the embodiment represented, the controller 15 is also used to guide the pulling operation-for example, the rotating and extracting of the single crystal 5 and the rotating and raising of the crucible 3. For initiating the supply of gaseous dopant to the surface of the melt 4, the dopant crucible 11 is heated by means of the crucible heater 12. During this, the controller 15 keeps the control valve 16 and the isolation valve 17 (where present) closed. The solid dopant in the dopant crucible 11 is initially preheated to a temperature below the sublimation temperature, until the pressure in the sublimating unit 2 has reached a mandated threshold. The temperature of the crucible heater 12 is subsequently increased to a target temperature above the sublimation temperature, resulting in a further pressure increase in the sublimating unit 2. The controller 15 brings the control valve 16 into a mandated open condition and opens, where appropriate, the isolation valve 17 as soon as the difference between the pressure in the sublimating unit 2 and the pressure in the reactor chamber 1 has grown to a predetermined value. The open condition of the control valve 16 is subsequently controlled, with the command variable of the control being a setpoint pressure in the sublimating unit 2. If the stock of solid dopant in the dopant crucible is dwindling, the pressure in the sublimating unit 2 falls. When the pressure has fallen to a mandated value, the control valve 16 and, when present, the isolation valve 17 are closed. After that, if required, still during the pulling process for the single crystal 5, the dopant crucible 11 may be loaded with further solid dopant and a new cycle of supplying the gaseous dopant to the surface of the melt 4 may be commenced.

In accordance with the preferred embodiment shown in FIG. 1, the lower end of the conduit 6 has the same distance from the surface of the melt 4 as does the lower end of the heat shield 10. In the case of this embodiment, furthermore, the profile of the conduit 6 in the reactor chamber 1 is designed such that the conduit 6 passes through the heat shield 10, and the lower end of the conduit 6 is disposed between a wall of the crucible 3 and the lower end of the heat shield 10.

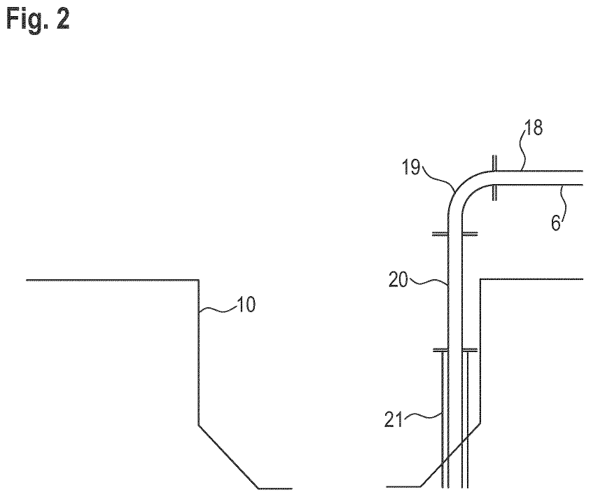

In accordance with this preferred configuration and the representation in FIG. 2, the conduit 6 in the reactor chamber 1 is subdivided into three portions, these being an upper portion 18 of stainless steel, a middle portion 19 of CFC (carbon fiber composite), and a lower portion 20 of quartz, surrounded at its lower end by a CFC jacket.

The effectiveness of the present disclosure was tested using, as an example, the production of a single silicon crystal having a diameter of 200 mm in a facility comprising substantially the features represented in FIG. 1. The sublimating unit came from the manufacturer Riber from France.

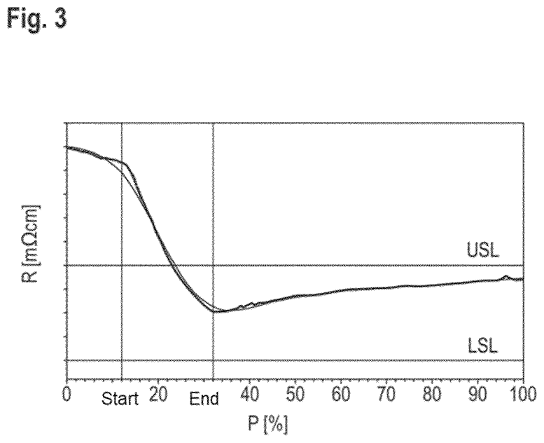

First, the single crystal was pulled to the point of an upper, cylindrical portion with basic phosphorus doping, which had been added to the melt prior to the pulling by means of a doping bell. The process of the present disclosure was used to show that the electrical resistivity of the single crystal can be lowered further and can be kept virtually constant, until the conclusion of the pulling procedure, between a lower limit LSL and an upper limit USL. FIG. 3 represents the outcome in the form of a resistance measurement. The resistance profile is shown from the start of the cylindrical portion with position P=0 to the end of the cylindrical portion with position P=100. The supplying of gaseous dopant in accordance with the present disclosure, in the form of a volume stream of dopant gas, took place during the pulling of the cylindrical portion of the single crystal between the positions denoted start and end. By application of the process of the present disclosure, it was possible to lower the resistivity in the single crystal to less than 1 mΩcm.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

### LIST OF REFERENCE SYMBOLS USED

1 Reactor chamber
2 Sublimating unit
3 Crucible
4 Melt
5 Single crystal
6 Conduit
7 Heating apparatus
8 Pulling apparatus
9 Magnetic field coil
10 Heat shield
11 Dopant crucible
12 Crucible heater
13 Weighing cell
14 Mass flow controller
15 Controller
16 Control valve
17 Isolation valve
18 Upper portion
19 Middle portion
20 Lower portion
21 CFC jacket

1. A process for producing a single silicon crystal doped with n-type dopant by pulling the single crystal, surrounded by a heat shield having a lower end, in a reactor chamber by the Czochralski (CZ) method from a melt contained in a crucible, the process comprising:
heating solid dopant in a dopant crucible of a sublimating unit outside the reactor chamber by a crucible heater to a temperature at which a gaseous dopant is formed; and
supplying the gaseous dopant in a form of a volume stream of dopant gas through a conduit having a lower end to a surface of the melt, which comprises:
bringing a control valve, which is between the sublimating unit and the reactor chamber, into a mandated open state as soon as a pressure difference between the pressure in the sublimating unit and the pressure in the reactor chamber has grown to a predetermined value; and
controlling the open state of the control valve with a setpoint pressure in the sublimating unit as command variable and the pressure difference as controlled variable of the control.

2. The process as claimed in claim 1, wherein the controlling of the open state takes the form of a proportional-integral-derivative (PID) control.

3. The process as claimed in claim 1, wherein the lower end of the conduit has a same distance from the surface of the melt as does the lower end of the heat shield.

4. The process as claimed in claim 1, wherein the conduit passes through the heat shield, the lower end of the conduit being disposed between a wall of the crucible and the lower end of the heat shield.

5. The process as claimed in claim 1, wherein the conduit is divided into an upper portion of stainless steel, a middle portion of carbon fiber-reinforced composite (CFC), and a lower portion of quartz clad with CFC.

6. The process as claimed in claim 1, wherein the conduit is closed between the sublimating unit and the reactor chamber by an isolation valve before the dopant crucible is reloaded with further solid dopant.

7. The process as claimed in claim 1, wherein the temperature of the dopant crucible is raised shortly before the solid dopant contained therein is used up.
